(19) United States
(12) Patent Application Publication
(10) Pub. No.: US 2005/0175770 A1
(43) Pub. Date: Aug. 11, 2005

(54) Fabricating an electrode for use in organic electronic devices

(75) Inventors: Liang-Sheng Liao, Rochester, NY (US); Joseph K. Madathil, Rochester, NY (US); Pranab K. Raychaudhuri, Rochester, NY (US); Ching W. Tang, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/775,360

(22) Filed: Feb. 10, 2004

(51) Int. Cl. B05D 5/12; C23C 16/00

(52) U.S. Cl. 427/124; 427/255.28

(57) ABSTRACT

A method of forming an electrode including providing a plurality of evaporation materials in solid-state forms, wherein the differences of the vapor pressure between each of the evaporation materials are within two orders of magnitudes at a selected evaporation temperature and placing the evaporation materials into a single evaporation source in an evaporation chamber. The method also includes pumping the evaporation chamber down to a predetermined vacuum condition and heating the evaporation source to a predetermined temperature and evaporating the materials to form the electrode.

### FIELD OF INVENTION

The present invention relates to providing a method to fabricate an electrode for use in an organic electronic device. More specifically, this invention relates to fabricating an electrode using a thermal evaporation method.

### BACKGROUND OF THE INVENTION

Organic electronic devices including organic optoelectronic devices are, or will be, useful in many applications. Organic electronic devices are the devices comprising at least two electrodes and at least one layer of organic medium between the electrodes, such as organic electroluminescence (EL) devices, organic thin film transistors, organic photovoltaic devices, organic memory devices, and some types of organic sensors. For a more specific example, an organic EL device (also known as organic light-emitting device, organic light-emitting diode, or OLED) is an electronic device that emits light in response to an applied potential, wherein the structure of the device comprises, in sequence, an anode, an organic EL medium, and a cathode. The organic EL medium disposed between the anode and the cathode is commonly comprised of an organic hole-transporting layer (HTL) and an organic electron-transporting layer (ETL). Holes and electrons recombine and emit light in the ETL near the interface of HTL/ETL. Tang, et al. demonstrated highly efficient OLEDs using such a layer structure in “Organic Electroluminescent Diodes”, Applied Physics Letters, 51, 913 (1987) and in commonly assigned U.S. Pat. No. 4,769,292. Since then, numerous OLEDs with alternative layer structures and using many different types of organic EL materials have been disclosed.

The cathode plays an important role in the overall performance of organic electronic devices. For example, in an OLED, the cathode injects electrons into the ETL during operation. In order to achieve good electron injection from the cathode into the organic layer, the cathode would be preferably made of low work function (<4.0 eV) metal. However, most of pure low work function metals, such as alkali metals, are very reactive in the atmosphere conditions, rendering them practically useless as a single layer electrode. Therefore, instead of using pure low work function metal as a cathode, it is common to use a metal alloy having both a low work function metal and a higher work function metal as a cathode, such as Mg:Ag disclosed by Tang, et al. in U.S. Pat. No. 4,885,211. It is also common to use a bilayer structure having both an electron-injecting layer and a high work function metal capping layer as a cathode, such as a LiF/Al bilayer structure disclosed by Hung, et al., in U.S. Pat. No. 5,776,622.

There are several ways to fabricate the cathode useful in organic electronic devices, such as ion sputtering, electron-beam evaporation, and thermal evaporation. Thermal evaporation is a simple way to fabricate a cathode. This method is compatible with the deposition of organic layers. However, two thermal evaporation sources (or boats) are usually needed in making a metal alloy cathode or a cathode having a bilayer structure. If only one evaporation source is used in making a cathode, this cathode may not be able to have good electron-injecting property, good optical reflectivity, nor good adhesion onto the surface of an organic layer. For example, although a thermally evaporated Ag layer can form a good optical reflector and good conductor, it cannot form a good cathode having satisfied electron-injecting property due to its high work function. Although a thermally evaporated Mg layer is more stable than alkali metals, the Mg layer cannot adhere onto the surface of organic layer, resulting in dark spots and poor electron injection. Good cathode can be formed when both Ag and Mg are co-evaporated from different sources. Obviously, two evaporation sources are needed for co-evaporation. Moreover, it is time consuming to adjust the alloy composition ratio by tuning the deposition rates of each evaporation source.

Recently, more organic layers are using in forming an OLED with high luminous efficiency and long lifetime, such as an OLED having a hole-injecting layer, an HTL, a first light-emitting layer (LEL), a second LEL, a hole-blocking layer, an ETL, and an electron-injecting layer. The LELs can consist of two hosts with one dopant, or even two hosts with two dopants. As a result, more evaporation sources in an evaporation chamber have to be assigned for organic evaporation. However, the number of evaporation sources is limited in an evaporation chamber. If transferring the unfinished device out to another chamber for cathode fabrication by breaking the vacuum, the resulting device may not have good performance due to exposure to air during device fabrication. Therefore, it is necessary to use a single evaporation source in the same chamber for an electrode fabrication.

### SUMMARY OF THE INVENTION

It is therefore an object of the present invention to provide a method to thermally evaporate a plurality of materials from a single source (or boat) to form an electrode for use in organic electronic devices.

It is another object of the present invention to simplify the fabrication of an electrode for use in organic electronic devices.

It is yet another object of the present invention to reduce fabrication time of organic electronic devices.

These objects are achieved by providing a method, comprising:
a) providing a plurality of evaporation materials in solid-state forms, wherein the differences of the vapor pressure between each of the evaporation materials are within two orders of magnitudes at a selected evaporation temperature;
b) placing the evaporation materials into a single evaporation source in an evaporation chamber;
c) pumping the evaporation chamber down to a predetermined vacuum condition; and
d) heating the evaporation source to a predetermined temperature and evaporating the materials to form the electrode.

The present invention makes use of a single evaporation source to fabricate an electrode for use in organic electronic devices. The organic electronic devices, for example, the OLEDs with a cathode made by this method, can have the same performance as the OLEDs with a cathode made by a conventional method (i.e., with more than two evaporation sources). Using this method to fabricate an electrode for use in organic electronic devices can save one evaporation source for other material evaporation. It can also simplify the fabrication of an electrode and shorten the fabrication time of organic electronic devices.

### BRIEF DESCRIPTION OF THE DRAWINGS

FIG. 1 is a block diagram showing the steps involved in a method to fabricate a binary alloy cathode on organic layers in an OLED according to the prior art;

FIG. 2 is a block diagram showing the steps involved in a method to fabricate an electrode on organic layers in an organic electronic device according to the present invention;

FIG. 3 is a schematic showing an evaporation source having one compartment used in forming an electrode according to the present invention;

FIG. 4 is a schematic showing another evaporation source having two compartments used in forming an electrode according to the present invention; and

FIG. 5 is a schematic showing another evaporation source having three compartments used in forming an electrode according to the present invention.

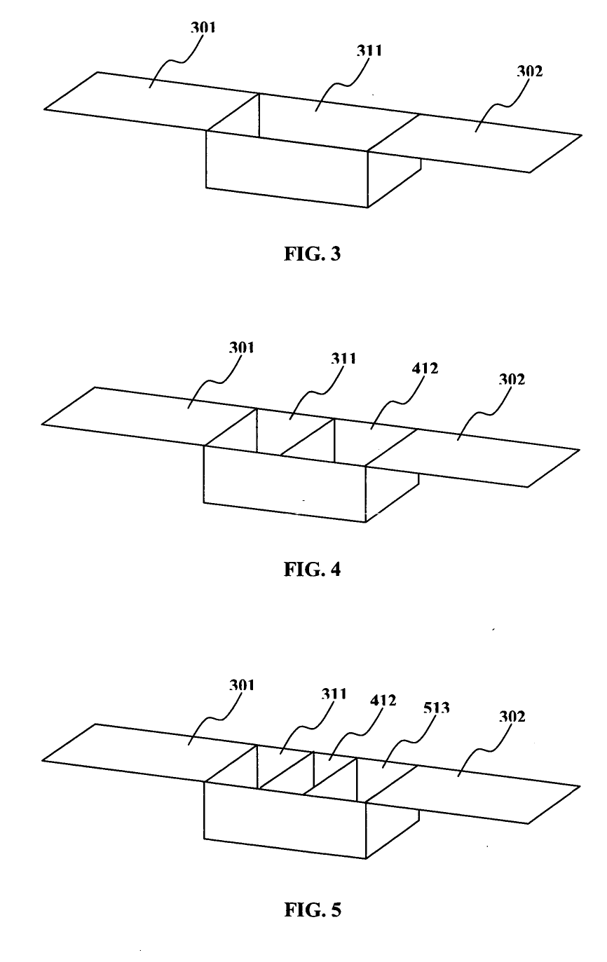

FIGS. 3, 4, and 5 are scaled and shaped for ease of visualization rather than dimensional accuracy.

### DETAILED DESCRIPTION OF THE INVENTION

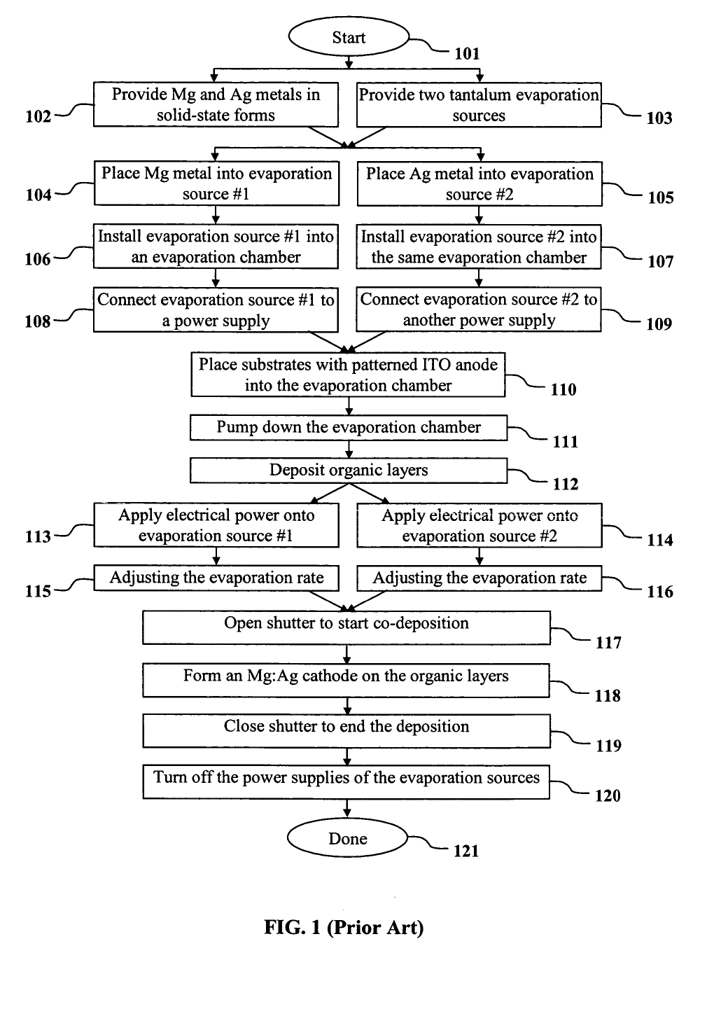

In order to fully appreciate the method to fabricate an electrode for use in an organic electronic device in the present invention, a prior art method to fabricate an Mg:Ag cathode for use in OLEDs is described with reference to FIG. 1.

There is shown a block diagram in FIG. 1, comprising the steps in one embodiment of a method for fabricating an Mg:Ag cathode in accordance with the prior art. At the start (Step 101) of the process, Mg and Ag metals are provided in solid-state forms (Step 102), and two tantalum evaporation sources are also provided (Step 103). Then the Mg metal is placed into evaporation source No. 1 (Step 104) and the Ag metal is placed into evaporation source No. 2 (Step 105). Then evaporation sources No. 1 and No. 2 are installed into an evaporation chamber (Step 106 and Step 107), and both evaporation sources are connected to the power supplies, respectively (Step 108 and Step 109). Since this cathode is fabricated on top of organic layers, the following steps are also necessary. Substrates having a patterned indium-tin-oxide (ITO) anode are placed into the evaporation chamber (Step 110). Then the evaporation chamber is closed and pumped down to a vacuum condition of about 10⁻⁶ Torr (Step 111). Then organic layers are deposited onto the substrates (Step 112). After the deposition of organic layers, electrical power is applied to evaporation source No. 1 and No. 2, respectively (Step 113 and Step 114). Then the evaporation rate of Mg is adjusted to 1.0 nm/s (Step 115) and the evaporation rate of Ag is adjusted to about 0.1 nm/s (Step 116). When the evaporation rates of both Mg and Ag are stabilized, the shutter is opened to start co-deposition of Mg and Ag on to the organic layers (Step 117). During the co-deposition, Mg:Ag cathode is formed on the organic layers (Step 118). Then the shutter is closed (Step 119) and the power supplies of the evaporation sources are turned off (Step 120) to end the deposition (Step 121).

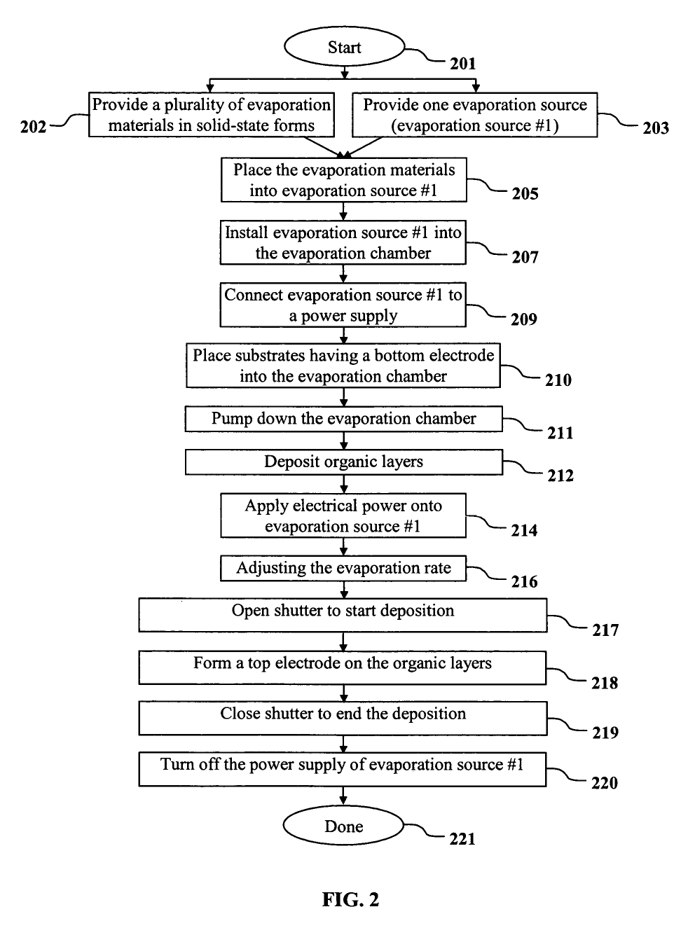

Turning now to FIG. 2, there is shown a block diagram comprising the steps in one embodiment of a method for fabricating an electrode in accordance with the present invention. At the start (Step 201) of the process, a plurality of evaporation materials is provided in solid-state forms (Step 202), and a single evaporation source (evaporation source No. 1) for electrode evaporation is provided (Step 203). Then the evaporation materials are placed into evaporation source No. 1 (Step 205). Then evaporation source No. 1 is installed into an evaporation chamber (Step 207) and connected to a power supply (Step 209). Since this top electrode is fabricated on top of organic layers, the following steps are also necessary: Substrates having a bottom electrode are placed into the evaporation chamber (Step 210). Then the evaporation chamber is closed and pumped down to a vacuum condition of about 10⁻⁶ Torr (Step 211). Then organic layers are deposited onto the substrates (Step 212). After the deposition of organic layers, electrical power is applied to evaporation source No. 1 (Step 214). Then the evaporation rate from the single evaporation source of the evaporation materials is adjusted to 0.5˜1.0 nm/s (Step 216). Then the shutter is opened to start deposition of the evaporation materials on the organic layers (Step 217). During the deposition, the top electrode is formed on the organic layers (Step 218). Then the shutter is closed (Step 219) and the power supply of evaporation source No. 1 is turned off (Step 220) to end the deposition (Step 221).

The method in accordance with the present invention in FIG. 2 is five steps less than the prior art method in FIG. 1. The method in accordance with the present invention needs only a single evaporation source to fabricate an electrode containing more than one composition. This method can also save fabrication time because it is not necessary to take a long time to adjust the deposition rates of two sources. Moreover, it is not necessary to keep a constant composition ratio of the two metals as in the prior art which uses two sources.

In the following description, two terms, “vapor pressure” and “evaporation temperature”, will be used. The term “vapor pressure” is the pressure created by the gas phase of the evaporation material at a certain temperature in a vacuum. The vapor pressure curves of some evaporation materials can be found in, for example, the Vapor Pressure Curves of the Elements have been printed by EPI MBE Products Group and EPI EUROPE, and they can also be found at http://www.veeco.com/learning_vaporelements.asp). The term “evaporation temperature” is the temperature at which a practical evaporation rate (such as 0.5˜1.0 nm/s in some cases) of the material could be achieved. The evaporation rate of a material is mainly determined by the vapor pressure of the material at a certain evaporation temperature.

At step 202 in FIG. 2, each provided evaporation material has its own vapor pressure at a selected evaporation temperature. In the present invention, it has been found that if the difference of the vapor pressure between two metals is greater than two orders of magnitudes at a selected evaporation temperature, and if these metals are placed in a single evaporation source for evaporation, only one metal is evaporated from the source with a practical evaporation rate to form a substantially pure layer consisting of the metal having a higher vapor pressure. For example, at the evaporation temperature of about 500° C., the deposition rate of Mg metal can be as high as about 1 nm/s, while that of Ag metal is substantially zero. Therefore, if Mg metal and Ag metal are placed in a single evaporation source for evaporation, only Mg evaporates, because the vapor pressure of Ag metal is seven orders of magnitudes lower than that of Mg metal at that temperature. Since this is a substantially pure Mg layer, this layer does not have good adhesion to the organic layer and it is not a good electrode for organic electronic devices as disclosed by Tang et al. in U.S. Pat. No. 4,885,211. However, when Mg metal with Yb metal (or Mg metal with Sb metal) is placed in a single evaporation source for evaporation, both Mg and Yb (or both Mg and Sb) can be evaporated to form a film with Mg as a major composition, and Yb (or Sb) as aminor composition at the evaporation temperature of about 500° C. The difference of the vapor pressure between Mg and Yb (or between Mg and Sb) is less than two orders of magnitudes at that temperature, according to the aforementioned Vapor Pressure Curves of the Elements. This Yb or Sb incorporated Mg layer is adhesive to the organic layer to form a good electrode which is comparable to a Mg:Ag electrode for use in OLEDs. Incorporating Yb or Sb into Mg electrode enhances the adhesion of Mg on the surface of the organic layer. It is believed that a reasonably low concentration of Yb or Sb is enough to form nucleation sites on the surface of the organic layer to facilitate the growth of Mg film, as discussed by Liao et al. in U.S. Patent Application 2003/0152801 A1. For this purpose, the concentration of the incorporated metal in Mg electrode can be as low as 1 mol. %. The other purpose of incorporating Yb or Sb into Mg electrode is to improve chemical stability and carrier injection ability of the electrode. For this purpose, the concentration of the incorporated metal in Mg electrode can be as high as 50 mol. %. Therefore, at step 202 in FIG. 2, the differences of the vapor pressure between each of the evaporation materials are within two orders of magnitudes at a selected evaporation temperature. And the concentration range of the incorporated materials in the electrode can be varied from 1 mol. % to 50 mol. %.

At step 202 in FIG. 2, the plurality of evaporation materials includes metals, metal compounds, or the combination thereof. For example, the plurality of metals can include Mg in combination with Yb, Sb, Sr, or Zn, include Al in combination with Sn, Cu, Nd, Sc, or Au, or include Ag in combination with Dy, Ga, Er, Al, In, or Mn. The plurality of evaporation materials can also include the combination of metal and organometallic compound, or the combination of metal and polymeric material. Furthermore, the plurality of evaporation materials can include the combination of metal, metal compound, and organometallic compound, or can include the combination of metal, metal compound, and polymeric material.

At step 203 in FIG. 2, the single evaporation source is made of metal or compound, wherein the metal or the compound has a melting point higher than 1500° C. Specifically, the evaporation source can be made of tantalum, iridium, molybdenum, platinum, tungsten, stainless steel, carbon, boron nitride, aluminum oxide, or quartz, and it can have different sizes and shapes. The evaporation source can have one or more compartments to contain evaporation materials. When the evaporation materials are placed into the evaporation source, the evaporation materials can be separated into each of the compartments in the evaporation source, or can be mixed together in the evaporation source. Shown in FIGS. 3-5 are the different evaporation sources in accordance with the present invention. The evaporation source shown in FIG. 3 has two electrical connectors (301 and 302) and one compartment (311). The mixed evaporation materials can be conveniently contained in this source. The evaporation source shown in FIG. 4 has two compartments (311 and 412), and the evaporation source shown in FIG. 5 has three compartments (311, 412, and 513). The number of compartments of the evaporation source can be more than three, depending on need. The evaporation sources having multiple compartments are suitable for separating the evaporation materials.

### EXAMPLES

The present invention and its advantages can be better appreciated by the following inventive and comparative examples. For purposes of brevity, the materials and layers formed therefrom will be abbreviated as given below.
ITO: indium-tin-oxide; used in forming the transparent anode on glass substrates.
CFx: polymerized fluorocarbon layer; used in forming a hole-injecting layer on top of ITO.
NPB: N,N′-di(naphthalene-1-yl)-N,N′-diphenyl-benzidine; used in forming the hole-transporting layer.
Alq: tris(8-hydroxyquinoline)aluminum(III); used in forming the light-emitting layer and the electron-transporting layer.
Li: lithium; used as n-type dopant in forming the n-type doped electron-transporting layer to improve electron injection and transport.
Mg:Ag: an electrode formed by co-evaporating magnesium and silver from two evaporation sources.
Mg:Yb: an electrode formed by evaporating both magnesium and ytterbium from a single evaporation source.
Mg:Sb: an electrode formed by evaporating both magnesium and antimony from a single evaporation source.

In the following examples, the thickness of the organic layers and the doping concentration were controlled and measured in situ using calibrated thickness monitors (INFICON IC/5 Deposition Controller). The electroluminescence characteristics of all the fabricated devices were evaluated using a constant current source (KEITHLEY 2400 SourceMeter) and a photometer (PHOTO RESEARCH SpectraScan PR 650) at room temperature. The color was reported using Commission Internationale de l'Eclairage (CIE) coordinates, CIEx,y. During the operational lifetime test, the devices being tested were driven at a current density of 80 mA/cm² at room temperature.

### Example 1 (Comparative Example)

The preparation of a conventional OLED is as follows: A ˜1.1 mm thick glass substrate coated with a transparent ITO conductive layer was cleaned and dried using a commercial glass scrubber tool. The thickness of ITO is about 42 nm and the sheet resistance of the ITO is about 68 Ω/square. The ITO surface was subsequently treated with oxidative plasma to condition the surface as an anode. A layer of CFx, 1 nm thick, was deposited on the clean ITO surface as the hole-injecting layer by decomposing CHF₃ gas in an RF plasma treatment chamber. The substrate was then transferred into a vacuum deposition chamber (TROVATO MFG. INC) for deposition of all other layers on top of the substrate. All organic materials were purified by gradient vacuum sublimation before use. The following layers were deposited in the following sequence by evaporation from a heated boat under a vacuum of approximately 10⁻⁶ Torr:
(1) a HTL, 75 nm thick, consisting of NPB;
(2) a LEL, 20 nm thick, consisting of Alq;
(3) an ETL, 40 nm thick, consisting of Alq doped with 1.2% Li by volume; and
(4) a cathode, approximately 150 nm thick, consisting of Mg:Ag with the volume ratio of 10:1.0 and formed by co-evaporating magnesium and silver from two evaporation sources.

After the deposition of these layers, the device was transferred from the deposition chamber into a dry box (VAC Vacuum Atmosphere Company) for encapsulation. The EL performance of the device, measured at a current density of 20 mA/cm², is shown in Table I, wherein the drive voltage, luminance, luminous efficiency, color coordinates CIEx,y, and the T₅₀(RT) (a lifetime, i.e. a time at which the luminance retains 50% of its initial value after being operated at 80 mA/cm² at room temperature) are listed.

### Example 2

An OLED was constructed in the manner described in Example 1, except that in step (4), a cathode, approximately 150 nm thick and consisting of Mg:Yb with an approximate volume ratio of 10:(0.5˜0.1), is formed by evaporating both magnesium and ytterbium from a single evaporation source. The EL performance of the device, measured at a current density of 20 mA/cm², is shown in Table I, wherein the drive voltage, luminance, luminous efficiency, power efficiency, color coordinates CIEx,y, and the T₅₀(RT) (at 80 mA/cm²) are listed.

### Example 3

An OLED was constructed in the manner described in Example 1, except that in step (4), a cathode, approximately 150 nm thick and consisting of Mg:Sb with an approximate volume ratio of 10:(0.5˜0.1), is formed by evaporating both magnesium and antimony from a single evaporation source. The EL performance of the device, measured at a current density of 20 mA/cm², is shown in Table I, wherein the drive voltage, luminance, luminous efficiency, power efficiency, color coordinates CIEx,y, and the T₅₀(RT) (at 80 mA/cm²) are listed.

TABLE I

| | | | | | | Initial | T₅₀(RT) |
|---|---|---|---|---|---|---|---|
| Example (Type) | | | Luminous | | | Luminance | @ |
| (EL measured @ | Voltage | Luminance | Efficiency | | | @ 80 mA/cm² | 80 mA/cm² |
| 20 mA/cm²) | (V) | (cd/m²) | (cd/A) | CIEx | CLEy | (cd/m²) | (Hrs) |
| 1 (Comparative) | 5.71 | 595 | 2.98 | 0.332 | 0.547 | 2530 | 952 |
| 2 | 5.61 | 616 | 3.08 | 0.331 | 0.546 | 2619 | 1091 |
| 3 | 5.88 | 517 | 2.59 | 0.344 | 0.547 | 2159 | 1141 |

From the data shown in Table I, it is seen that OLEDs with the cathode fabricated in accordance with the present invention have comparable EL performance to that of the OLED with conventionally fabricated cathode. This indicates that the method to fabricate an electrode for use in organic electronic devices in accordance with the present invention is simple and useful.

The present invention has been described in detail with particular reference to certain preferred embodiments of OLEDs thereof. However, the present invention is not limited to the preferred embodiments, ant it is also applicable to other organic electronic devices. Therefore, it will be understood that variations and modifications can be effected within the spirit and scope of the invention.

### Parts List

101 start
102 provide Mg and Ag metals in solid-state forms
103 provide two tantalum evaporation sources
104 place Mg metal into evaporation source No. 1
105 place Mg metal into evaporation source No. 2
106 install evaporation source No. 1 into an evaporation chamber
107 install evaporation source No. 2 into an evaporation chamber
108 connect evaporation source No. 1 to a power supply
109 connect evaporation source No. 2 to a power supply
110 place substrates with patterned ITO anode into the evaporation chamber
111 pump down the evaporation chamber
112 deposit organic layers
113 apply electrical power onto evaporation source No. 1
114 apply electrical power onto evaporation source No. 2
115 adjusting the evaporation rate
116 adjusting the evaporation rate
117 open shutter to start co-deposition
118 form an Mg:Ag cathode on the organic layers
119 close shutter to end the deposition
120 turn off power supplies of the evaporation sources
121 end of deposition
201 start
202 provide a plurality of evaporation materials in solid-state forms
203 provide one evaporation source
205 place evaporation materials into evaporation source No. 1
207 install evaporation source No. 1 into an evaporation chamber
209 connect evaporation source No. 1 to a power supply
210 place substrates having a bottom electrode into the evaporation chamber
211 pump down the evaporation chamber
212 deposit organic layers
214 apply electrical power onto evaporation source No. 1
216 adjust the evaporation rate
217 open shutter to start deposition
218 form a top electrode on the organic layers
219 close shutter to end deposition
220 turn off the power supply of evaporation source No. 1
221 end of deposition
301 electrical connector
302 electrical connector
311 compartment
412 compartment
513 compartment

1. A method of forming an electrode, comprising:
a) providing a plurality of evaporation materials in solid-state forms, wherein the differences of the vapor pressure between each of the evaporation materials are within two orders of magnitudes at a selected evaporation temperature;
b) placing the evaporation materials into a single evaporation source in an evaporation chamber;
c) pumping the evaporation chamber down to a predetermined vacuum condition; and
d) heating the evaporation source to a predetermined temperature and evaporating the materials to form the electrode.

2. The method of claim 1 including:
a) monitoring the total evaporation rate to a predetermined value by adjusting the applied electrical power;
b) opening a shutter to start evaporation;
c) closing the shutter when the thickness of the electrode layer has reached a predetermined value; and
d) turning off the power supply.

3. The method of claim 1 wherein the plurality of evaporation materials includes metals, metal compounds, or the combination thereof.

4. The method of claim 3 wherein the plurality of metals includes Mg in combination with Yb, Sb, Sr, or Zn.

5. The method of claim 3 wherein the plurality of metals includes Al in combination with Sn, Cu, Nd, Sc, or Au.

6. The method of claim 3 wherein the plurality of metals includes Ag in combination with Dy, Ga, Er, Al, In, or Mn.

7. The method of claim 1 wherein the plurality of evaporation materials include the combination of metal and organometallic compound.

8. The method of claim 1 wherein the plurality of evaporation materials include the combination of metal and polymeric material.

9. The method of claim 1 wherein the plurality of evaporation materials include the combination of metal, metal compound, and organometallic compound.

10. The method of claim 1 wherein the plurality of evaporation materials include the combination of metal, metal compound, and polymeric material.

11. The method of claim 1 wherein the evaporation source is made of metal or compound, wherein the metal or the compound has a melting point higher than 1500° C.

12. The method of claim 10 wherein the evaporation source is made of tantalum, iridium, molybdenum, platinum, tungsten, stainless steel, carbon, boron nitride, aluminum oxide, or quartz.

13. The method of claim 1 wherein the evaporation source has one or more compartments containing evaporation materials.

14. The method of claim 1 wherein the evaporation materials are placed separately into each of the compartments in the evaporation source.

15. The method of claim 1 wherein the evaporation materials are mixed together in the evaporation source.
